(19) United States
(12) Patent Application Publication
(10) Pub. No.: US 2008/0036503 A1
(43) Pub. Date: Feb. 14, 2008

(54) VARIABLE THRESHOLD TRANSISTOR FOR THE SCHOTTKY FPGA AND MULTILEVEL STORAGE CELL FLASH ARRAYS

(75) Inventor: Augustine W. CHANG, San Jose, CA (US)

Correspondence Address: SAWYER LAW GROUP LLP, P O BOX 51418, PALO ALTO, CA, 94303, US

(73) Assignee: SUPER TALENT ELECTRONICS, INC., San Jose, CA (US)

(21) Appl. No.: 11/831,277

(22) Filed: Jul. 31, 2007

Related U.S. Application Data
(63) Continuation of application No. 10/817,201, filed on Apr. 2, 2004.

(51) Int. Cl. H03K 19/00

(52) U.S. Cl. 326/101

(57) ABSTRACT

An IC solution utilizing mixed FPGA and MLC arrays is proposed. The process technology is based on the Schottky CMOS devices comprising of CMOS transistors, low barrier Schottky barrier diode (SBD), and multi-level cell (MLC) flash transistors. Circuit architectures are based on the pulsed Schottky CMOS Logic (SCL) gate arrays, wherein a variable threshold NMOS transistor may replace the regular switching transistor. During initialization windows, existing FPGA programming techniques can selectively adjust the VT of the switching transistor, re-configure the intra-connections of the simple SCL gates, complete all global interconnections of various units. Embedded hardware arrays, hardwired blocks, soft macro constructs in one chip, and protocols implementations are parsed. A wide range of circuit applications involving generic IO and logic function generation, ESD and latch up protections, and hot well biasing schemes are presented. The variable threshold transistors thus serve 3 distinctive functions.

### CROSS-REFERENCE TO RELATED APPLICATIONS

Under 35 USC § 120, this application is a continuation application and claims the benefit of priority to U.S. patent application Ser. No. 10/817,201, filed Apr. 2, 2004, entitled “Variable Threshold Transistor for the Schottky FPGA and Multilevel Storage Cell Flash Arrays”, all of which is incorporated herein by reference.

### FIELD OF THE INVENTION

The present invention relates generally to the mixed logic and memory devices in single chip and more particularly to the use of variable threshold transistors for low power logic and multilevel storage cell (MLC) arrays.

### BACKGROUND OF THE INVENTION

1. Mixed Signal Circuits for Super IC

The electrical erasable and programmable EEPROM memory has received wide attention in the last decade. Both the technological advances and broad product applications has made it the most emerging candidate for implementing SOC level memory component integrations.

On the process and device technology front, the general practice has been focused on the miniaturization of the physical size of the storage bit, scaling down the cell operating voltages and currents and therefore lowering power consumptions, implementing multilevel signal storages per physical cell area, building up on chip apparatus to manage per bit, byte, large and partial arrays, resource sharing schemes. The ultimate goals are to achieve the highest level of system integration with mixed analog, memory and logic circuits (AMLC) in a common chip; and therefore improve IC devices with performance, reliability, system efficiency and capacity etc.

2. The Densest Cells of Any Memory and Logic Arrays in Si

A FLASH memory cell, with its multiple bit (2) storage capability in one physical cell layout, is a good choice to implement information storage devices. The density, power, and speed capability of flash arrays exceed that of rotating disks, so the semiconductor EEPROM is replacing the mechanical disk medium in many applications. The Flash may also replace DRAM/SRAM if the speed performance is improved besides its superior property of nonvolatile and density of multi-level per cell for information storage. However, little work was developed to employ the Flash technology to logic applications. Some work was reported to use the EEPROM as switch to wire or reconfigure circuits in a FPGA design methodology. Altera and Xilinx offer field programmable chips to interconnect various CMOS hardware constructs to form complex circuit functions. The standalone FPGA devices support re-configurable control functions that are easy to change with instant deliverable parts.

Accordingly, what is needed is a system and method for providing a FLASH array which overcomes the above-identified problems. The present invention addresses such a need.

### SUMMARY OF THE INVENTION

An IC solution utilizing mixed FPGA and MLC arrays is proposed. The process technology is based on the Schottky CMOS devices comprising of CMOS transistors, low barrier Schottky barrier diode (SBD), and multi-level cell (MLC) flash transistors. Circuit architecture are based on the pulsed Schottky CMOS Logic (SCL) gate arrays, wherein a variable threshold NMOS transistor may replace the regular switching transistor. During initialization windows, existing FPGA programming techniques can selectively adjust the VT of the switching transistor, re-configure the intra-connections of the simple SCL gates, complete all global interconnections of various units. Embedded hardware arrays, soft macro constructs in one chip, and protocols are parsed.

The Variable Threshold transistors thus serve 3 distinctive functions. It acts as an analog device to store directly nonvolatile information in SCL gates. It couples the diode tree logic functions. Finally, it stores and operates large amount of information efficiently. The mixed SCL type FPGA and MLC storages shall emerge as the most compact logic and memory arrays in Si technology. Low power, high performance, and high capacity ICs are designed to mix and replace conventional CMOS-TTL circuits. The idea of multi-value logic composed of binary, ternary, and quaternary hardware and firmware is also introduced.

### BRIEF DESCRIPTION OF THE DRAWINGS

FIG. 1A shows two embodiments of prior art implementations, one cell structure has the source drain buried beneath oxide region, the other has source drain reachable for metal contact wiring.

FIG. 1B shows the horizontal layout of the simplified VTL switching transistor.

FIG. 1C is the schematic diagram of prior art '800 SCMOS DTL logic gate.

FIG. 1D shows that the switch transistor can be replaced by a VT transistor.

FIG. 1E is the layout representation of the DTL gate with VT transistor.

FIG. 2 shows block diagram of a typical chip set device using the present invention.

FIG. 3 shows critical view of the SCMOS transistors, diodes, and VT device

FIG. 4 shows SBD I-V curve employing various contact metals that have high or low contact barriers.

FIG. 5 shows that SBD circuit models of anode, both high and low resistance regions of the bulk cathode.

FIGS. 6A and 6B show SBD works from the literature.

FIG. 7 shows IC logic gate design trend for 5 decades. The layout showing areas of signal fan-in and fan-out.

FIG. 8 shows the table of the proposed design library entries. System controllers for the various chip sets.

FIG. 9 shows two versions of the pulsed SCL inverters.

FIG. 10 shows two versions of the Schmitt trigger IBUF.

FIG. 11 shows several versions of IOBUF.

FIG. 12 shows the circuits of a 4-bit transceiver.

FIG. 13 shows the circuit of a GTL differential IBUF. And OBUF

FIG. 14 shows the circuit of a XOR4 implementation.

FIG. 15 shows the circuit of ring oscillator and D-latch.

FIG. 16 shows the circuit of D-Flip flop from SCL NOR, and the serial in to parallel out shift register.

FIG. 17 shows the circuit of D-Flip flop from SCL NAND.

FIG. 18 shows the circuit of a ac differential amplifier with latch.

FIG. 19 shows the circuit of a dual port SRAM implementation.

FIG. 20 shows the circuit of mask and fused ROM and PLA with SBD.

FIG. 20A shows a conventional CMOS transistor ROM.

FIG. 20B and FIG. 20C show a circuit diagram for SCL dynamic SBD ROM-double density faster access times (mask program and field program).

FIGS. 20D-20F illustrate Mask ROM.

FIGS. 20G and 20H illustrate two schemes to perform local interconnect.

FIG. 21 illustrates ESD input protection with SBD.

FIG. 22 illustrates such circuits used as level shifters and for the voltage reference circuits.

FIGS. 23A-23C illustrate such circuits used as clamp diodes of the parasitic NPN in the p-well region.

FIG. 23D illustrates such circuits used in the P-well/N-well to affect well biasing.

### DETAILED DESCRIPTION

The present invention relates generally to the mixed logic and memory devices in single chip and more particularly to the use of variable threshold transistors for low power logic and multilevel storage cell (MLC) arrays. The following description is presented to enable one of ordinary skill in the art to make and use the invention and is provided in the context of a patent application and its requirements. Various modifications to the preferred embodiment and the generic principles and features described herein will be readily apparent to those skilled in the art. Thus, the present invention is not intended to be limited to the embodiment shown but is to be accorded the widest scope consistent with the principles and features described herein.

1. The Variable Threshold Transistor for VTL and MLC Arrays

A device process, circuit, and system architecture of combined FPGA and EEPROM mass storage techniques in accordance with the present invention that will support both the variable threshold logic (VTL) array and multi-level storage cell (MLC) array implementations in a common substrate. Both the conventional CMOS transistor and the MLC transistor are utilized directly to implement generic binary logic functions. Besides these critical functions, the variable threshold transistor may serve as storage element, analog comparator, and multi-value logic defined by ternary and quaternary algebraic operators.

Unlike conventional binary logic, which was based on CMOS-TTL circuit architecture, the invention circuit was operated on the principle of pulsed SCMOS-DTL that was fully disclosed in U.S. Pat. No. 6,590,800. In the '800 patent, the SCMOS-DTL circuit was based on conventional transistors with fixed threshold (˜0.7V). Here the process technology of the switching transistor is further extended including a device with variable threshold, and field programmable. Armed with this powerful flexibility, the SCMOS process technology may support wide range of product and circuit applications. The exemplary circuit implementations in this article demonstrated some generic logic library entries. While the emerging design platform is compatible with conventional CMOS techniques, it outperforms conventional CMOS-TTL solutions by:

1) Employing highest density logic and memory circuit units

2) Consuming the lowest power

3) Increasing superior capacity

4) Offering field programming capability

2. The SCL Cells and MLC Cells Review

It is the object of the present invention is to mix the MLC storage arrays with the SCMOS based Schottky CMOS-DTL Logic (SCL) arrays on the same chip. Another object is to mix the hardwired implementations with the field programmable so that the cost and flexibility are compromised. Still another object is to implementing schemes allowing space and time multiplexing of the MLC transistor in a SCL circuit. By reconfiguring a MLC transistor in a SCL switch transistor, we augment the physical device to serve three distinctive roles; analog signal comparator, digital logic gating, and nonvolatile signal storage element. Still another object is to support special features (On chip transmission line termination, for instance) of certain circuit units such that performance is optimized. Still another object is to develop multi-value logic (MVL) circuit implementations. The MVL, a separate invention prosecution by the author, involves hardware and firmware supported arithmetic operations. Powerful ternary and quaternary logic circuits, algorithms, and algebraic operators are implemented. The capacity and efficiency of information access and process are greatly improved beyond the same supported by conventional binary circuits and Boolean algebra.

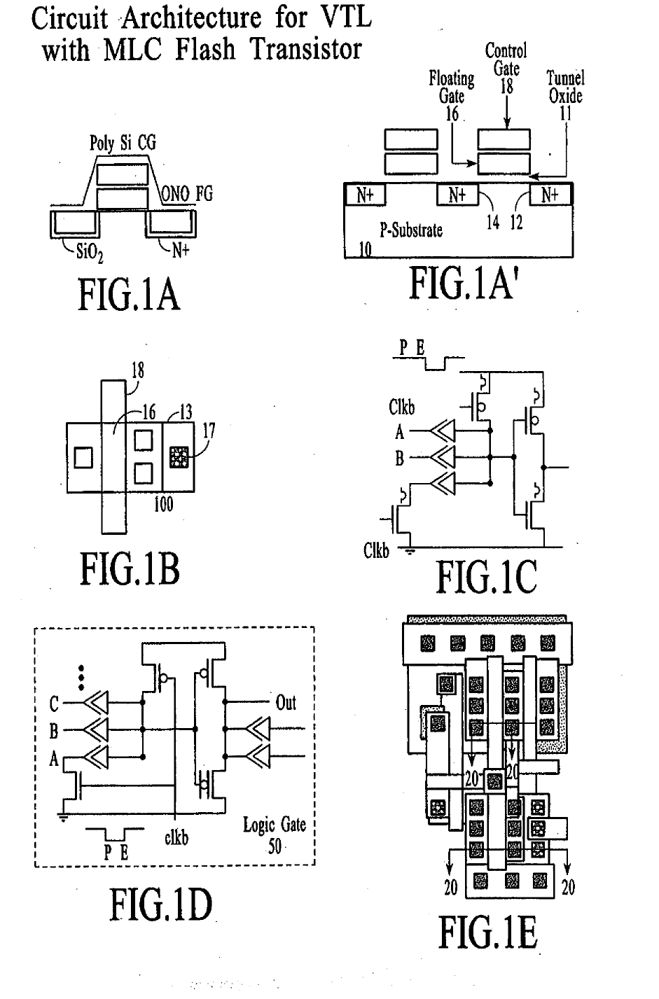

There are many ways of making MLC flash array cells. For the purpose of discussion, we show two embodiments of prior art implementations in FIG. 1A. One cell structure has the source drain buried beneath oxide region, the other has source drain reachable for metal contact wiring. The first type is best for implementing high-density NAND storage arrays. The second type can be used as re-configurable switching transistor in forming the SCMOS-DTL logic gates. FIG. 1B shows the horizontal layout of the simplified VTL switching transistor. FIG. 1C is the schematic diagram of prior art '800 SCMOS DTL logic gate. FIG. 1D shows the switch transistor can be replaced by a VT transistor. FIG. 1E is the layout representation of the DTL gate with VT transistor.

FIG. 1B is a simplified structure of a NMOS switch transistor horizontal layout, which has its gate region modified by adding a floating gate region 16 in the otherwise regular NMOS transistors with poly gate 18. This device may replace the regular NMOS switching transistor to transform a hardwired SCL FIG. 1C circuit to become field programmable (FIG. 1D). The modified layout art is shown in FIG. 1E.

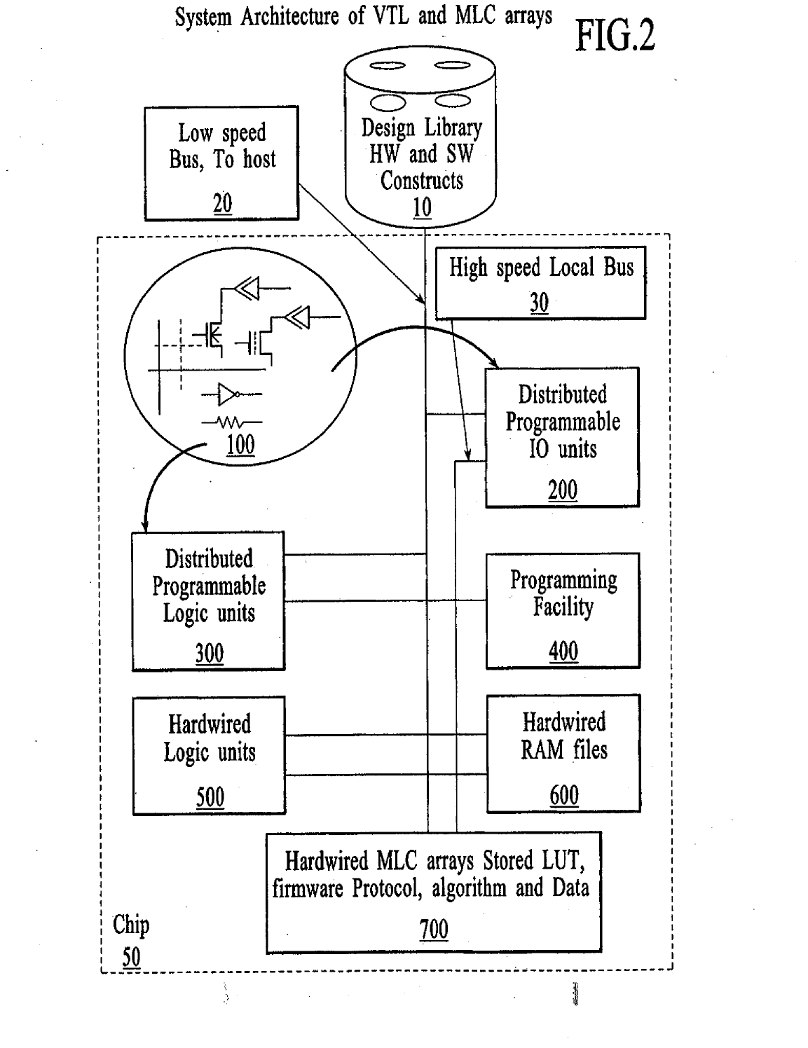

FIG. 2 depicts a chip 50 comprising of (off chip) design library 10, and at least one of the typical chips 50. Local constructs are the distributive 10 units 200, distributive logic units 300, Programming facility 400, hardwired RAM and ROM 500 including those one time programmable (OTP) by fuse or anti-fuse techniques, and MLC storage arrays 700, which store the data bits and LUT based software.

On chip facilities 400 are provided to program (Erase and write) the MLC and VT transistors to the desired threshold level during chip initialization procedures. Suitable local and global wiring tracks are allocated to reconfigure selected transistors both as the controls of interconnecting switches and as the switching transistor of the inverter. Suitable chip areas are allocated to support certain portions of hardware as hardwired logic and storage arrays, and another regions support programmable logic units and 10 blocks. One can drive the re-configuration processes by the stored LUT software and initialization procedures. The logic circuits and termination schemes once programmed can remain nonvolatile after power shut down yet are re-configurable when needed.

It is the object of this invention the logical units are formed by the pulsed DTL circuits, which only need Schottky diodes, standard CMOS and VT transistor switches, pass transistors, and power inverters. Since the circuit wiring is much simpler than CMOS-TTL, this new architect usually does not require conventional CMOS-TTL gate cells having more than 2-way inputs. Stacked transistor string is not required as the TTL circuits often do. In SCL, each of the SBD local IO ports occupy only the size of a contact hole to carry channels of logic signals as Fan-in and Fan out. Not only it saves physical space, but more importantly it is low power and faster. The circuit is dc static burning no power. Ac power is prorated by asynchronous pulsed cycles. The logic swing is lowered to 1.2V supply, the nets have lower stray capacitance, and there are no serial transistor paths with biennial RC time constant.

The simple circuit architecture of the SCL circuit simplified the reconfiguration tasks. It would be much more complicated if one tries to configure a TTL based conventional logic circuits.

The employment of the VT transistor in the DTL inverter allows the transistor to serve 3 distinct functions within one physical entity. It is a gating element to pass or block logics, analog signal comparator to sample and compare input signal against stored signal, and a nonvolatile multi-level information storage element. The logic function is instantiated by the clock transistor pairs, which either bias the diode tree to generate desired logic function or activate diode clamp. The logic function is further coupled through a simple inventor or chains of inverters for power amplifications. The logic functional constructs can be either hardwired CMOS-DTL (Default VT of 0.7V) implementations or soft macros subject to reconfiguration procedures. It may have instantiated VT for the switching transistor, intra and inter block circuit connections among the diode tree, and inverter(s). The instantiated circuit unit in at least one of the IO or Logic blocks shown in FIG. 2—100 comprising of resistors, clock transistors, regular pass transistors, VT switching transistors, MLC switches, local (dashed short bars) and global wiring tracks (long and solid bars).

FIG. 2 depicts a system environment to support field applications. The hardwired artwork and soft macro constructs are stored in a dedicated host system together with other essential files. All data can be transported to the slave or master device, which has certain predetermined hardwired constructs and pre-allocated re-configurable resources. One of the embodiments is illustrated in FIG. 2 chip 50. This device contains several functional units. There are plural IO units 200 which may be distributed along edges of the chip or scattered over the flip chip ball grids. Plural logic units 300 for state machines and other computing purposes, hardwired logic 500, RAM and ROM files 600. Inter unit interfaces are made of simple or complex re-configurable constructs. Dedicated programming overhead 400 and wiring tracks pass transistors, switches, are allocated to support logic and memory array formations and operations.

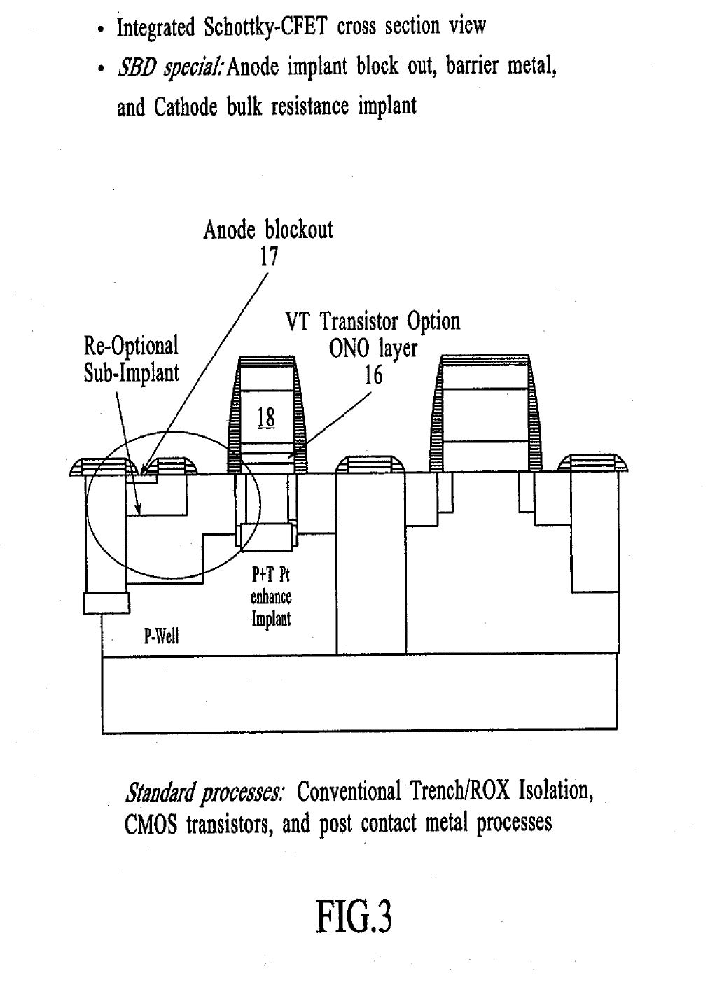

In one embodiment, the SCMOS device cross-section 200 of the switching transistor and the PMOS transistor is highlighted in FIG. 3. The SBD diode (regions 12, 13, 15, 17) is situated in the extension bed of NMOS transistors. The VT transistor 100 is a optional transistor with stacked floating gate 16 made of ONO material or buried poly conducting film. The regular NMOS is structured the same except without the floating gate. It is not the emphasis of the present invention to elaborate the process details of many prior art devices, but simply follows the current state of the arts in making the CMOS transistors and MLC transistors. Trench isolation is preferred to prevent lateral latch up action between the NMOS and PMOS gate array transistors and CMP is preferred for multiplayer wiring.

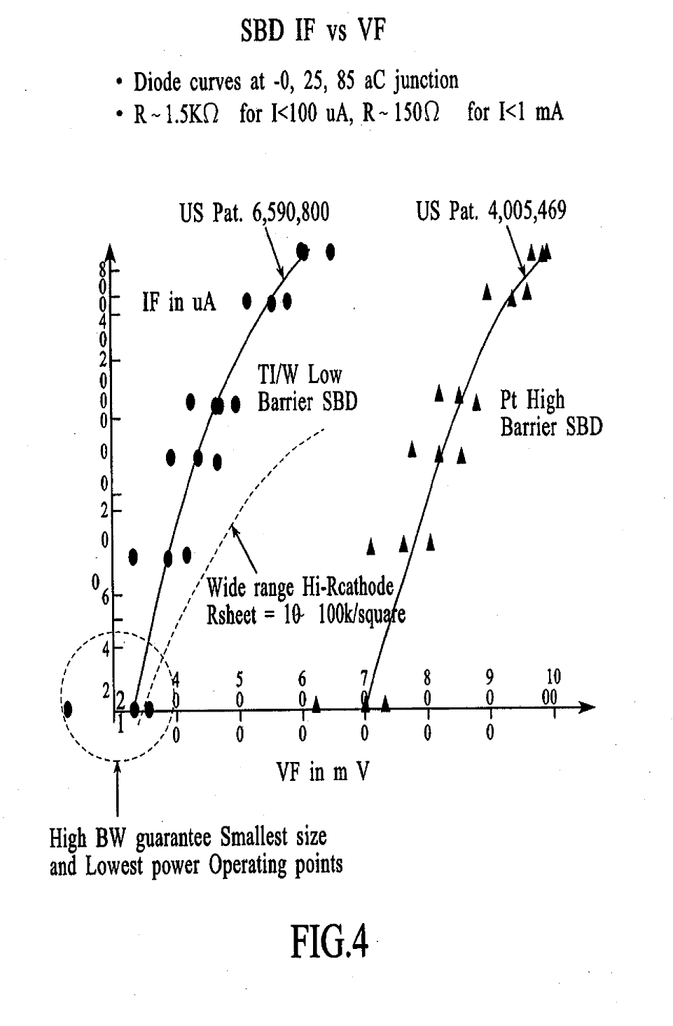

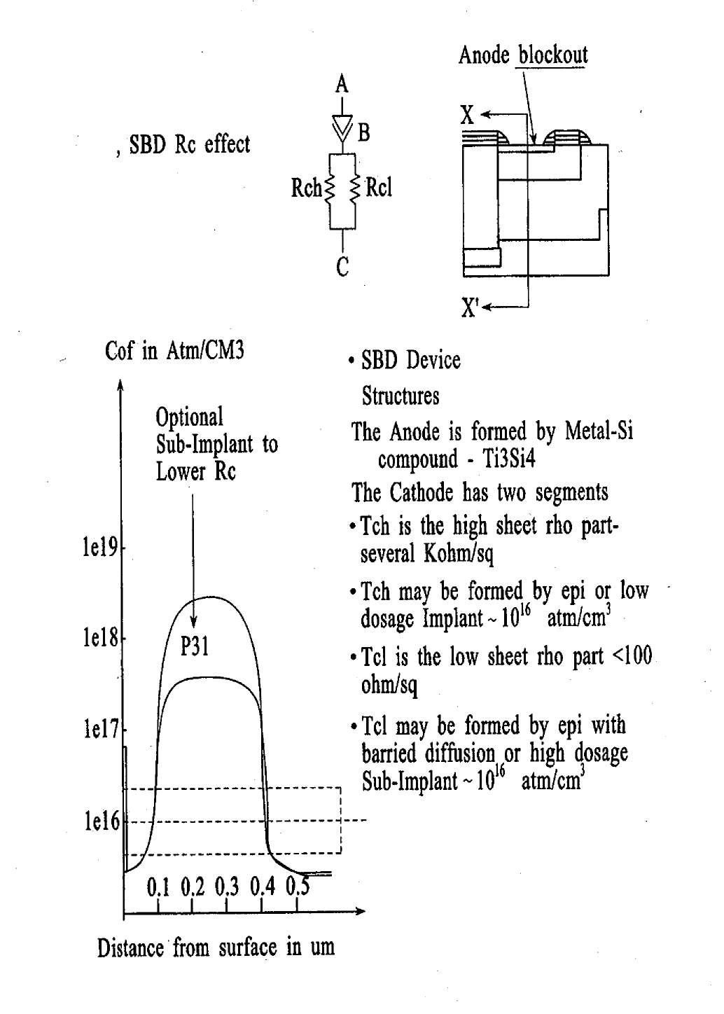

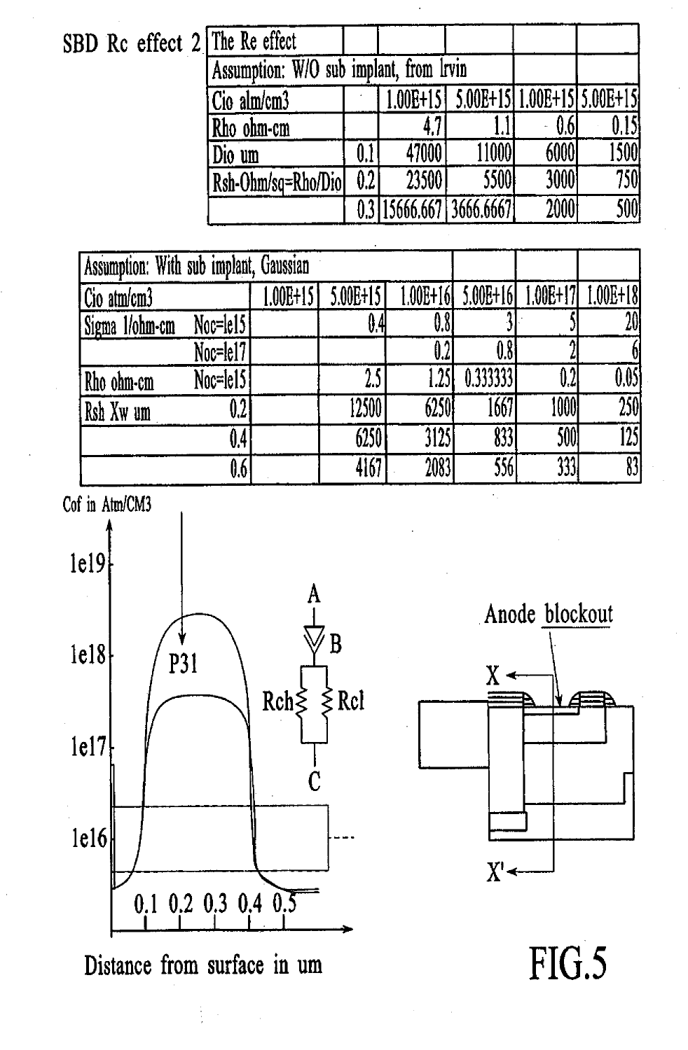

Several device cross-section views 20 are shown in FIG. 3. The floating gate can be of either the Oxide-Nitride-Oxide (ONO) layer or conducting poly Si films. The process flow should be compatible with any Flash technology, which also supports peripheral circuits build with regular NMOS and PMOS transistors. In addition, we shall introduce process deviations to add SBD steps with 1 extra (anode) and 1 optional cathode masks. The SBD may share its common cathode contact with NMOS source-drain. Its cathode bulk is consisting of N-bed 15 in the extended NMOS source-drain regions. Sub-implant region 13 are required if the application needs low cathode resistance from sheet rho of several k-ohms to lower than 100 ohms. The anode is made of metal silicide compounds with suitable work function difference with respect to its Si background material. For Ti/W layer with N-type Si at 1e16 atoms/cm³ impurity concentration, the barrier is expected to be around 0.52 V. The modeled IV curves are shown in FIG. 4. During the active state at ˜1 uA and 0.2 V forward, the on diode occupies smallest Si space and consumes the lowest power than any active on chip silicon components.

It can be seen in FIG. 1D, the SCL circuit configuration is extremely simple comparing to the conventional CMOS-TTL gates shown in FIG. 7. Since the diodes are integrated into the NMOS. The intra and inter gate connections are very little. Therefore this circuit architecture type is highly suitable for FPGA construct since both the VT adjustments and the final gate formation and interfaces can be handled with less programming facility overhead and wiring resources.

The VTL 200/300, Hardwired logic 400 (may be simple CMOS-TTL or SCL), OTP ROM and RAM 600, and MLC storage array 700 combination will ensure the chip constructs with best efficiency, performance, capacity, and flexibility. Besides, the VTL and firmware may deliver powerful multi-value logic and operations beyond what is achievable from the embedded constructs of traditional binary circuits. The reader is referred to a separate invention article by the author-quaternary logic implementations with VTL. Still another circuit implementations may turn the FIG. 1D logic gate into an analog signal comparator and as a dual bit information storage unit.

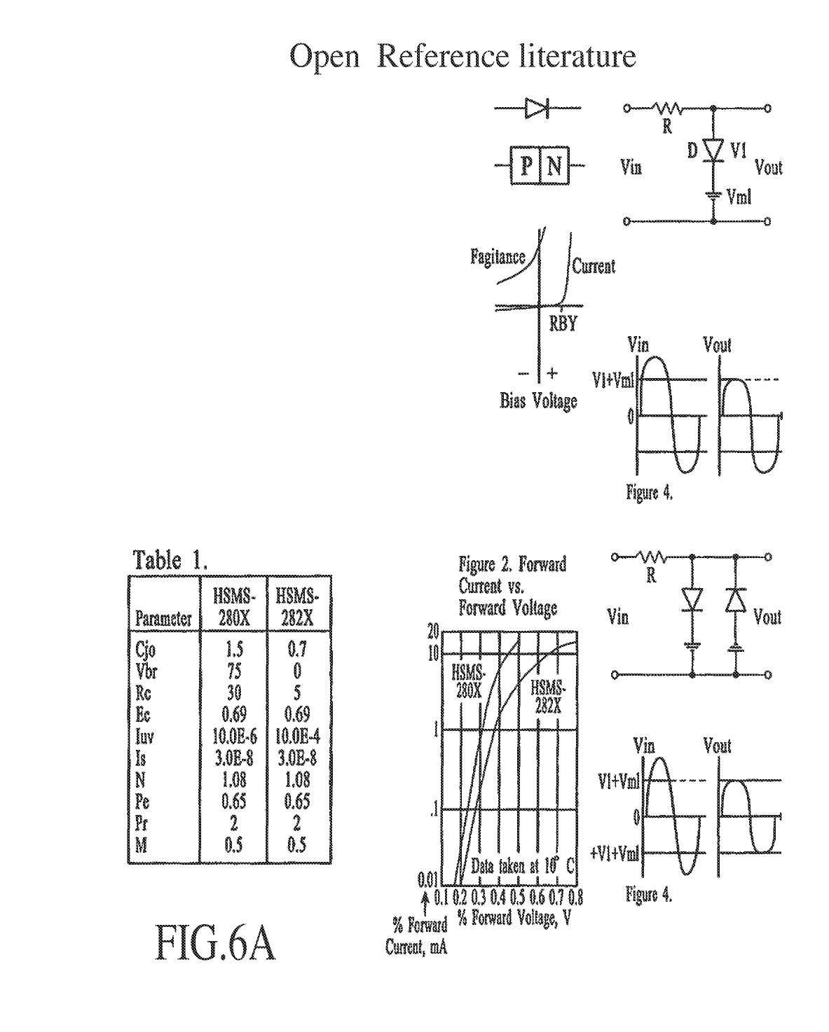

FIG. 4 shows the SBD I-V curves for two types of contact metals (Pt/Al diode and Ti/W diode), which yield cut-in voltage at 0.2˜0.3 V range and 0.7 V respectively. FIG. 5 suggested two types of substrates to prepare the N-Type background for making SBD.

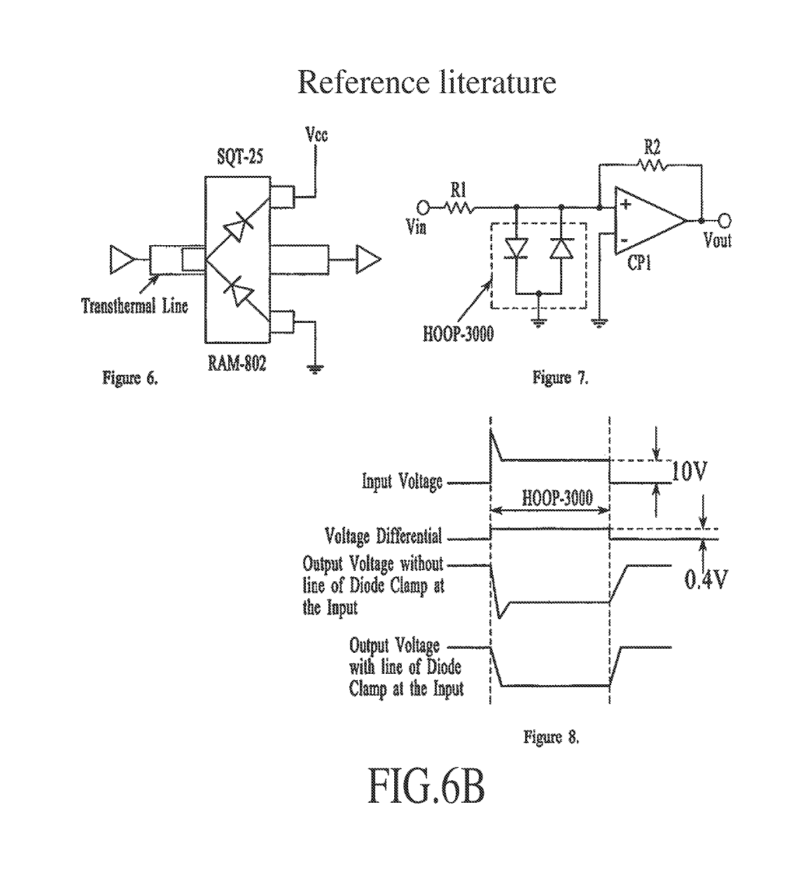

The SBD can be either Hi barrier or low barrier metal, but the surface concentration of the N-background is around 1e16 atoms/cm³. Deep buried sub-implant or EPI layer is required to achieve low surface concentrations. Some SBD work from HP were referenced in FIGS. 6A and 6B. The device exhibits 0.2V forward and leakage was under 1 nA at 9V reverse biasing. It was used as line clamp to contain over/undershoots.

FIG. 7 below shows the circuit layout and speed power charts comparing CMOS-TTL and SCMOS-DTL logic gates. Due to its small channel size and low power (1.2V) operations, the simple DTL circuits shall outperform the TTL circuits. We estimate it will mature within next decade with extremely dense bulk areas and thin film wiring. Logic gate consumes dynamic power in sub-femto joule range due to small physical size, low junction and wiring capacitances.

TABLE 1
IC circuit solution and cost trends
Figure of merit index comparison on NAND4 gate

| | | Area | Access | Power | Defect | AAP |
|---|---|---|---|---|---|---|
| Technology | Time | Normalized Cost figures | | | | |
| Bipolar TTL | 1980 | 100 | 100 | 100 | 100 | 1E8 |
| Bipolar ECL | 1985 | 200 | 10 | 200 | 200 | 8E7 |
| CMOS TTL | 2000 | 10 | 10 | 10 | 10 | 1E4 |
| CMOS-SDTL | 2004 | 2 | 2 | 2 | 2 | 16 |

Bipolar CMOS

| | | | | | |
|---|---|---|---|---|---|
| Tech rules/pars | 1970 | 1980 | 1990 | 2000 | 2010 |
| Gox/Wb Ang | 4000 | 2000 | 200 | 70 | 30 |
| H um leff | 6 | 3 | 1 | 0.25 | 0.07 |
| H um film | 1 | 0.5 | 0.4 | 0.3 | 0.2 |
| Contact/space um | 10 | 2 | 1.2 | 0.25 | 0.2 |
| Typ C load in F | 10 pF | 1 pF | 0.4 pF | 200 fF | 50 fF |
| Op. V volt | 8 | 5 | 3.3 | 2.5 | 1.2 |
| Op. I mA, CV * f | 1 mA | 0.1 mA | 0.01 mA | 1 uA | 10 nA |
| Speed nS | 70 | 10 | 3 | 500 pS | 200 pS |
| Power * Speed pJ | 560 | 5 | 0.1 | 0.03 | 1.3 fJ |
| W inch | 3.5 | 4 | 6 | 8 | 12 |
| Density Gates | 100 | 2000 | 20k | 200k | 1M |

Table 1 above cites design parameters used over 4 generations, from bipolar TTL, ECL to NMOS, and CMOS of ICs in the past 4 decades. The trend with SCMOS shall emerge in the next decade using the universal SCL FPGA and MLC storage array implementations.

Back to the system architecture shown in FIG. 2, we incorporate embedded RAM sub-systems encompassing Flash 700 and any memory arrays 600 (SRAM, DRAM, ROM) and programmable logic arrays. Low power and novel circuit means are disclosed to implement preferred embodiments at chip and PCB assembly levels. In a separate invention disclosure we propose distributive chip set solutions for USB2+ mass storage sticks and cards based on this architecture with mixed FPGA and MLC chips.

Initial Hardware Library Entries and Controllers

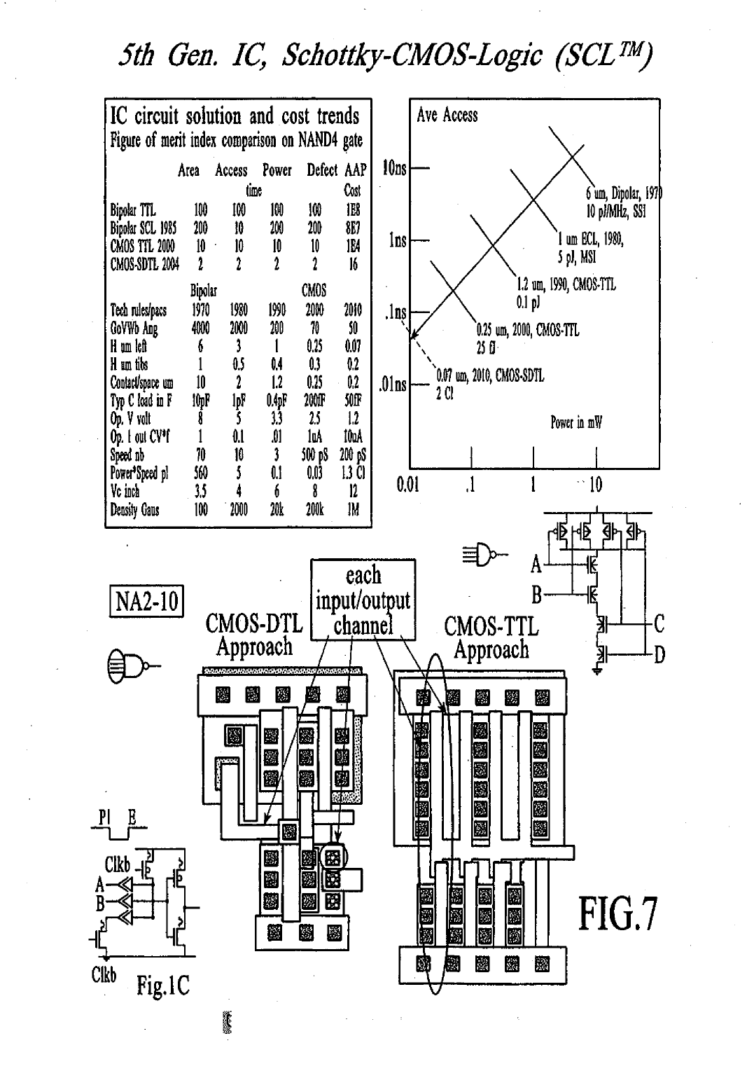

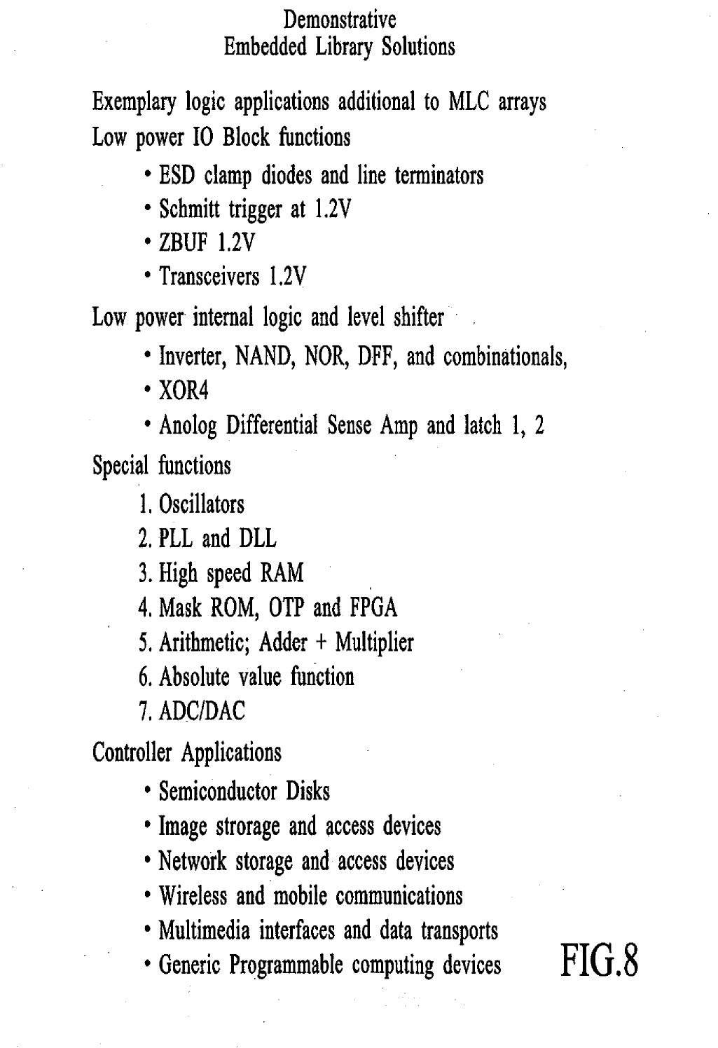

All circuits support conventional CMOS-TTL interface as well as SCL interface. They can be both hardwired for best speed or be implemented as FPGA soft macros to achieve flexibility or special performance features. They are as shown in FIG. 8. [0066]

1. Low Power 10 Block Functions
ESD clamp diodes and line terminators
Schmitt trigger at 1.2V
ZBUF 1.2V
Transceivers 1.2V

2. Low Power Internal Logic and Level Shifter
Inverter, NAND, NOR, DFF, and combinatorial.
XOR4
Analog Differential Sense Amp and latch 1, 2

3. Special Functions
Oscillators
PLL and DLL
High speed RAM
Mask ROM, OTP and FPGA
Arithmetic; Adder+Multiplier
Absolute value function
ADC/DAC

The library may also support low power high capacity controller chip designs, including but not limited to:
Semiconductor Disks
Image storage and access devices
Network storage and access devices
Wireless and mobile communications
Multimedia interfaces and data transports
Generic Programmable computing devices

It is clear that much more variations can be derived by the skilled from the teachings of this invention by mixing Flash array and FPGA for product applications at system and chip levels.

FIG. 7 contains the design parameter table and power-speed chart of IC implementations over 4 generations in the past 4 decades. We further project the SCL circuitry to emerge as the mainstream practices in the next decade since it possesses competitive attributes disclosed above in the present invention. The layout artwork of a typical NAND4 in SCL is compared with the same of a CMOS-TTL implementation. Besides area and power savings, one can see that the SCL is easier to reconfigure for it only has the NMOS of the first stage inverter to program. On the other hand, one would program 4 times for the MNOS transistors in the TTL gate.

The VTL and MLC implementations indeed possess the superior qualities than conventional binary CMOS-TTL hardware to access, transport, process and store large amount of information based on special and time multiplexing operations with Si semiconductors.

FIG. 8 summarizes a few library entries one can easily developed for generic product applications. The aims are to perform low power (1.2V supply) data access, transport, and storage functions, and it works well with existing CMOS-TTL macros with little modification for mixed macro interfaces (SCL and TTL).

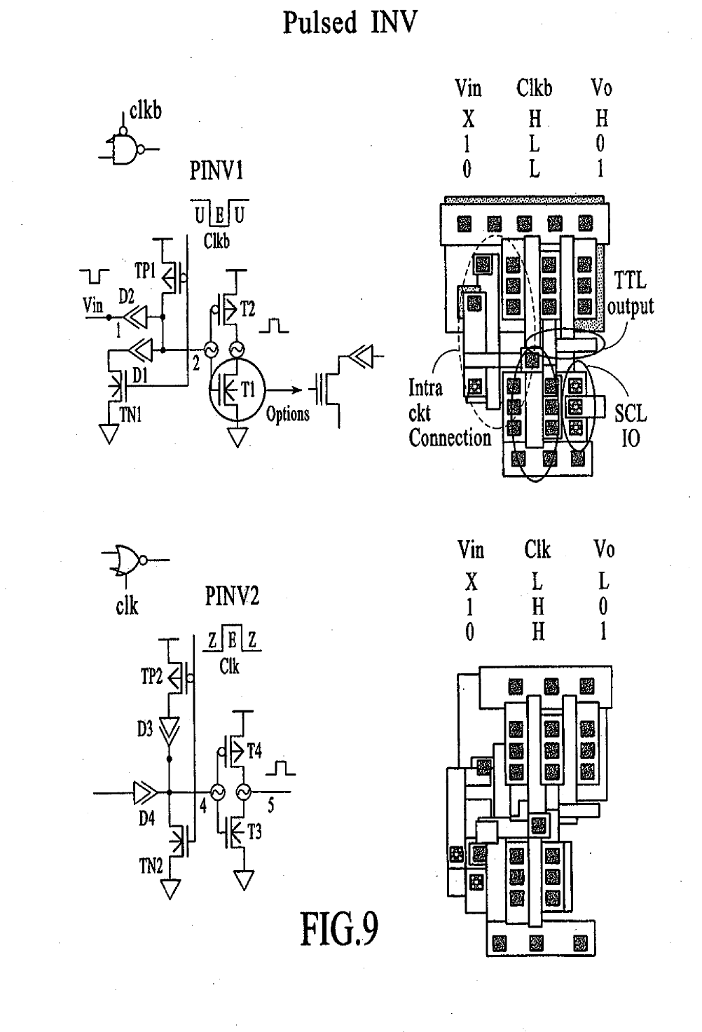

FIG. 9 details the specification of a SCL macro. There are truth table, symbol and schematic diagram, wave forms, and layout.

The inverters may have the following variations:

1) Straight CMOS transistors (Fixed VT and hardwired).

2) VT transistor as the NMOS transistor of the first stage inverter strings.

3) Add 2-way SBD tree and clock pair coupling to the inverter thus form either NOR or NAND based SCL inverter.

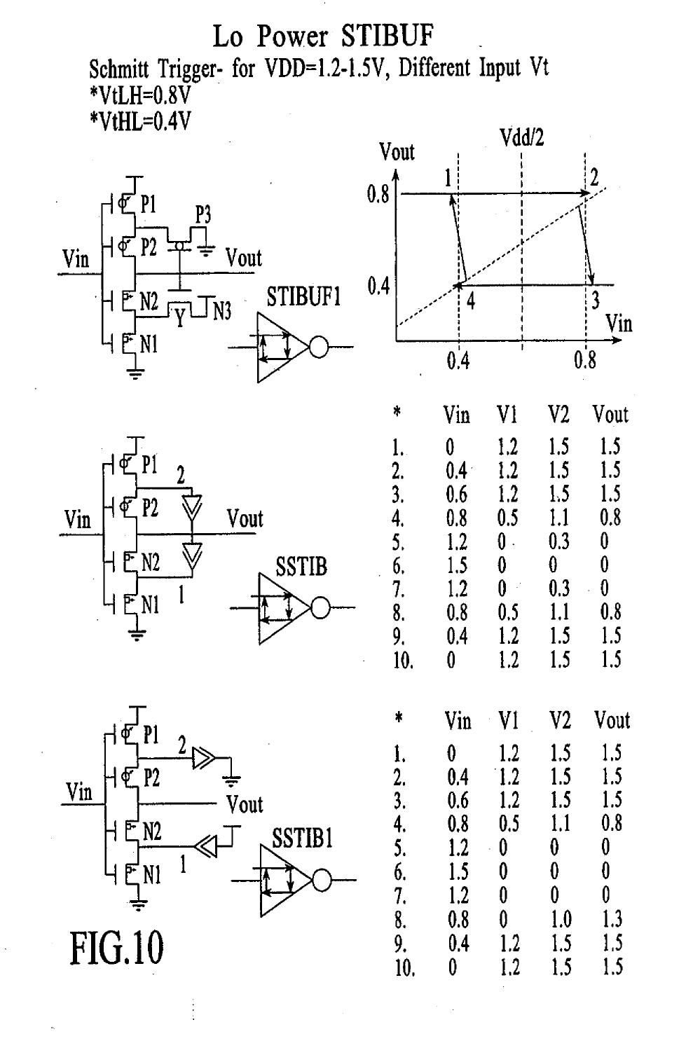

FIG. 10 discloses two schemes to make a Schmitt trigger. The trip points for H/L and L/H are 0.4 and 0.8V respectively.

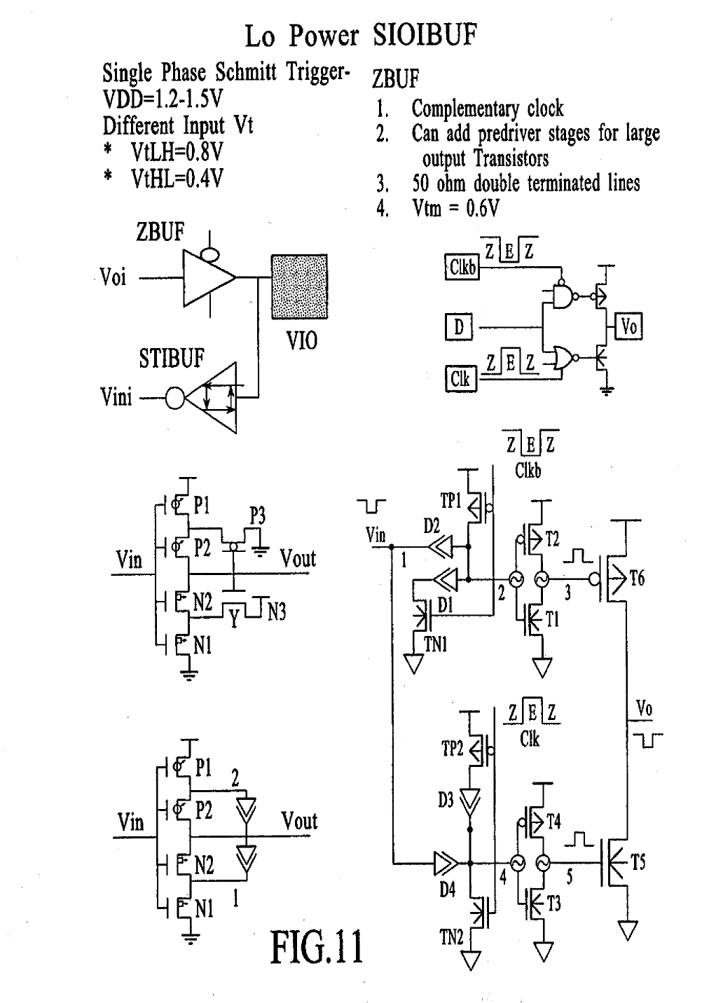

FIG. 11 discloses two schemes to make a 3 state OBUF. One for internal bus and one for line driver. IOBUF are formed with the addition of the Schmitt trigger IBUF.

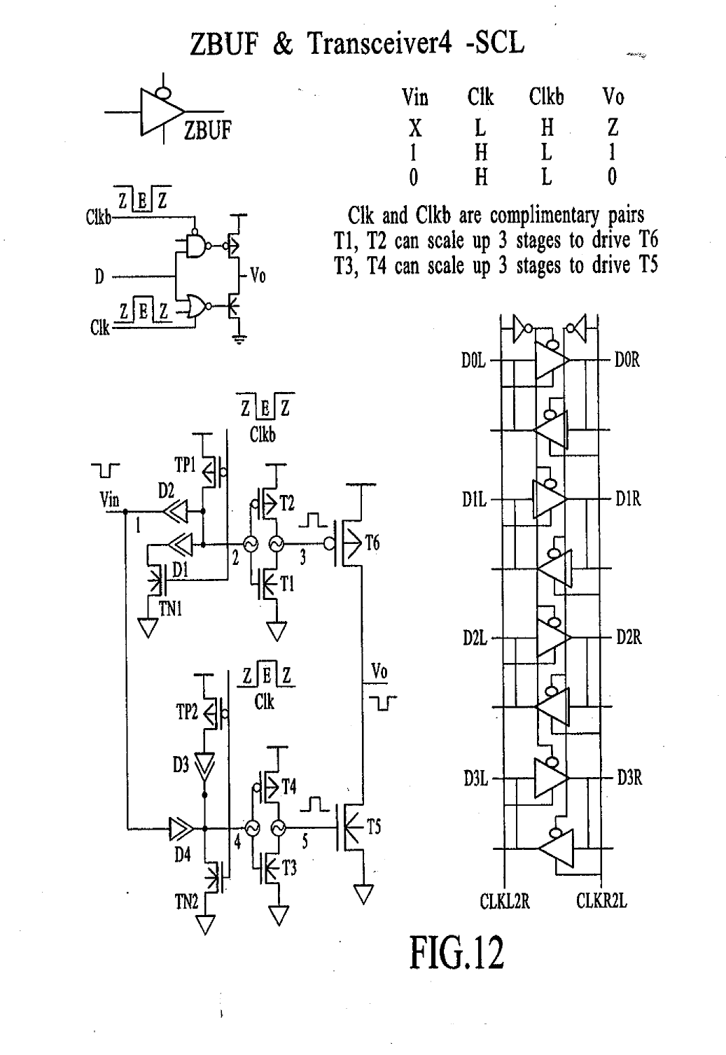

FIG. 12 discloses two schemes to make a 4 bit bi-directional transceiver.

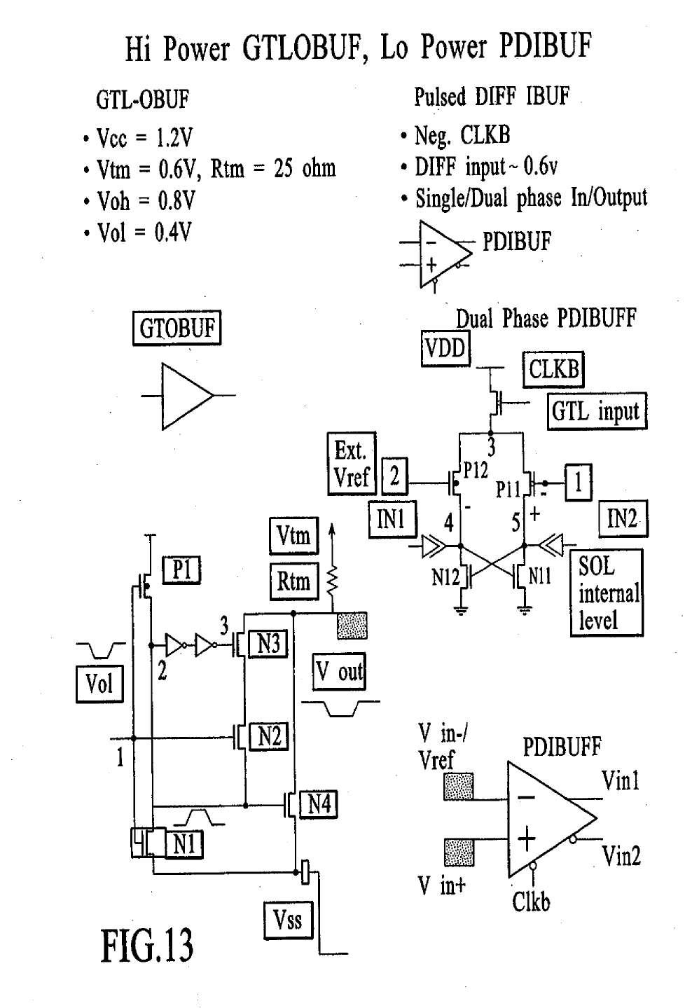

FIG. 13 discloses schemes to make a differential input amplifier, which can also be a general purpose operational amplifier. It may be used for input signal phase and frequency detector.

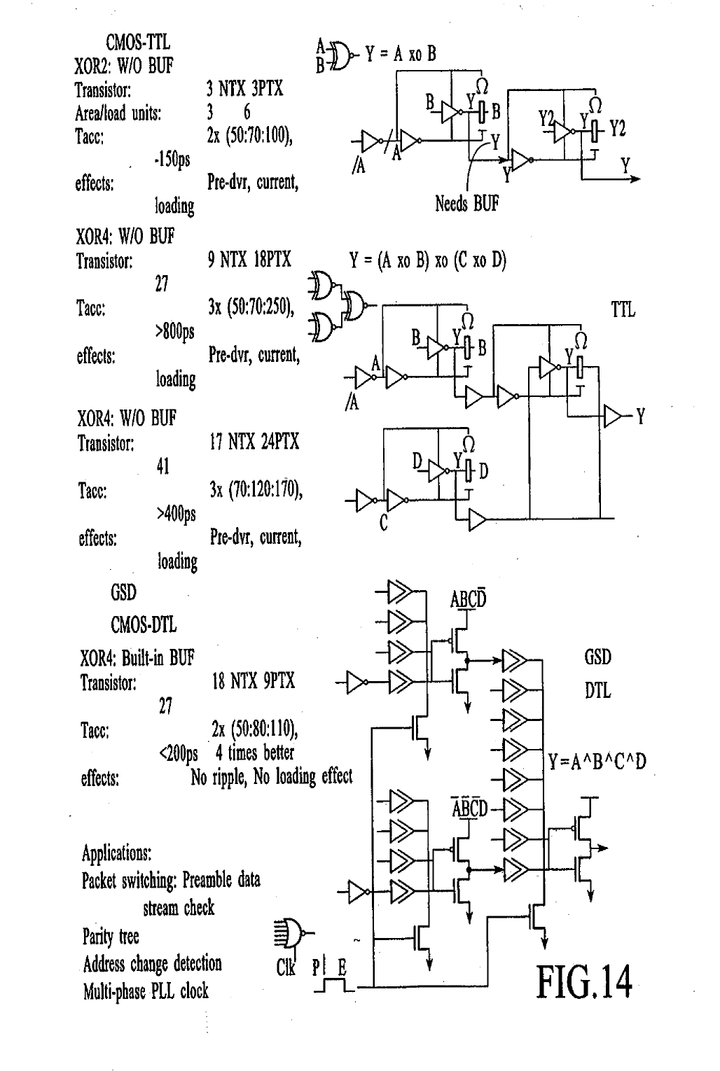

FIG. 14 compares schemes to implement XOR4 function. One way is by SCL with two stage 4 way and 8 way diode trees. The other is the classic CMOS-TTL. The SCL circuitry is smaller, yet 50% faster.

FIG. 15 discloses schemes to make ring oscillator and D-latch by mixed SCL and CMOS-TTL circuits. The 2 way CMOS-TTL Flip-flops may interface with SCL by adapting a SBD at the NMOS output. We deem the TTL performance is acceptable if fan-in is less than or equal to 2 way.

We further suggest that by adapting VT NMOS with SCL logic units, the volatile latch can be replaced by a nonvolatile MLC. Which is the simplest SCL circuit with single VT transistor element.

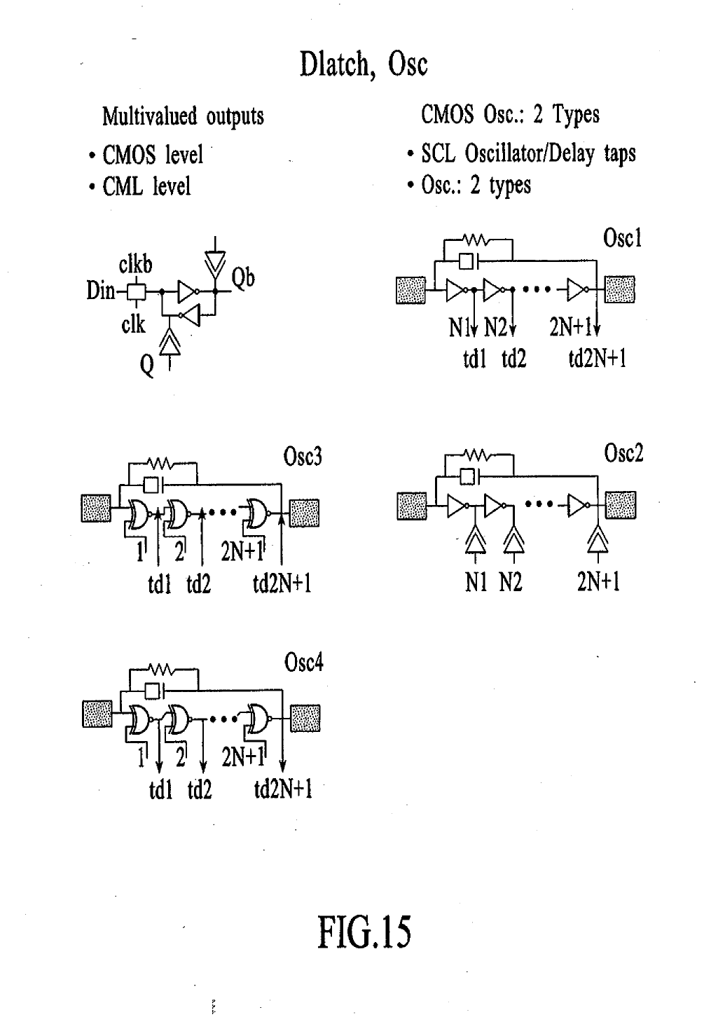

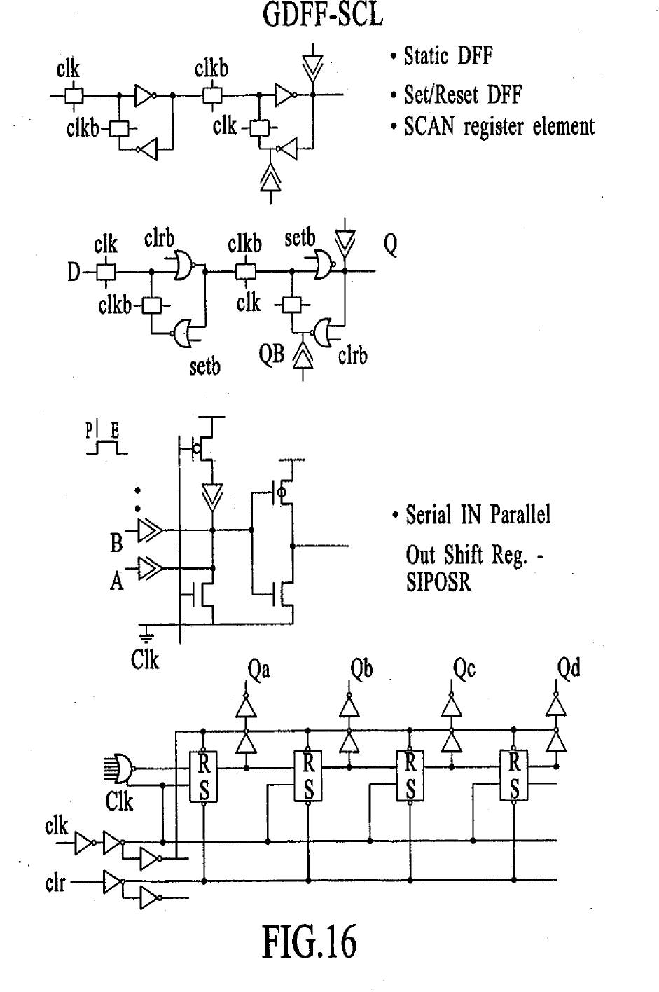

FIG. 16 discloses schemes to make D-flip-flop in CMOS-TTL and SCL. The Serial IN Parallel Out Shift Register are also illustrated.

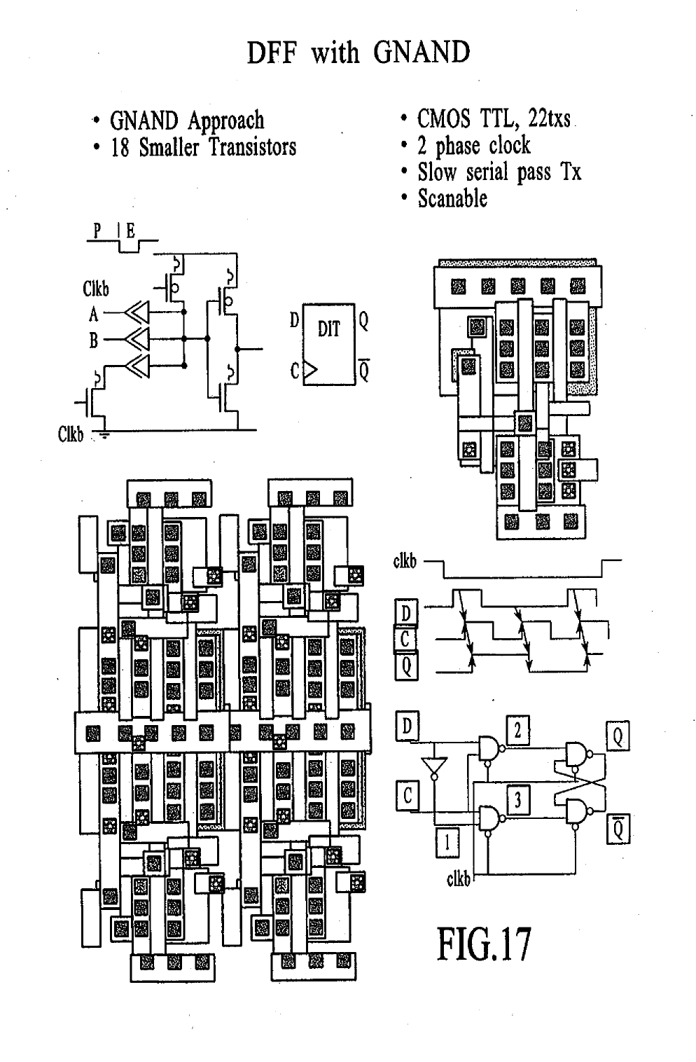

FIG. 17 discloses schemes to make complex functions by interconnecting simple building blacks. Automatic place and routing and logic synthesis procedures can be developed referring to prior arts software tools in simulations including waveform analysis.

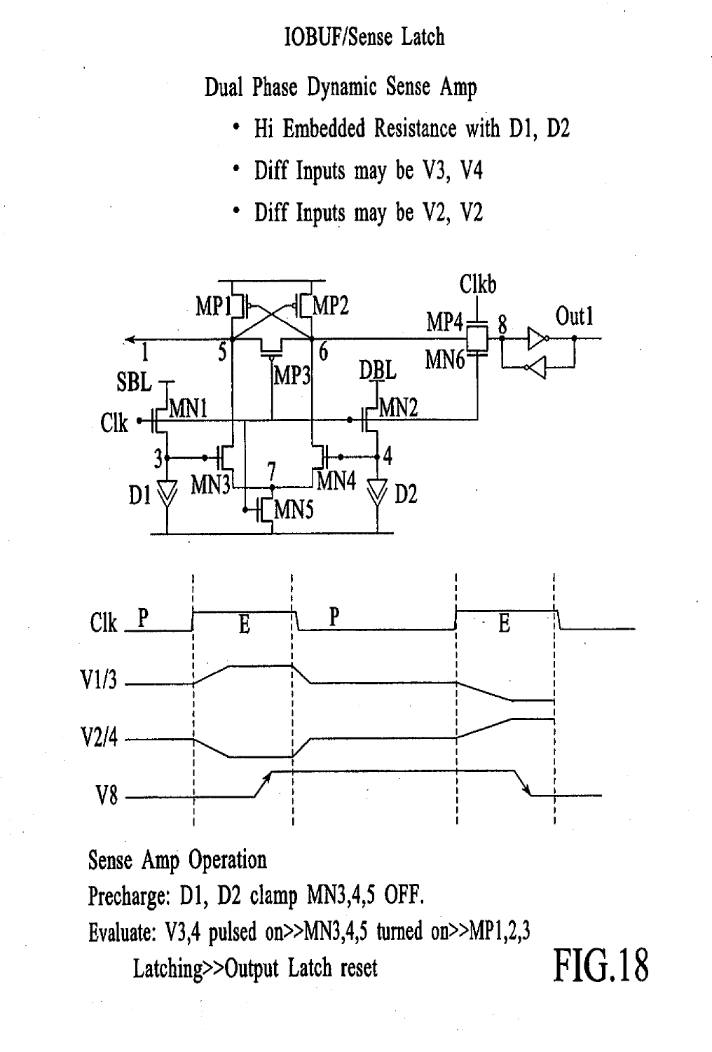

FIG. 18 discloses schemes to implement a small ac signal sense amplifier with latch. This latch works to catch small amplitude ac differential signals in a large RAM/ROM array. The SBD leg normally will clamp/disable the amplifier and latch. During the pulsed window, the high RC impedance of the SBD will boost both sides of the sense signals imposed on the gate. The signals are cross coupled and amplified to reach the latch.

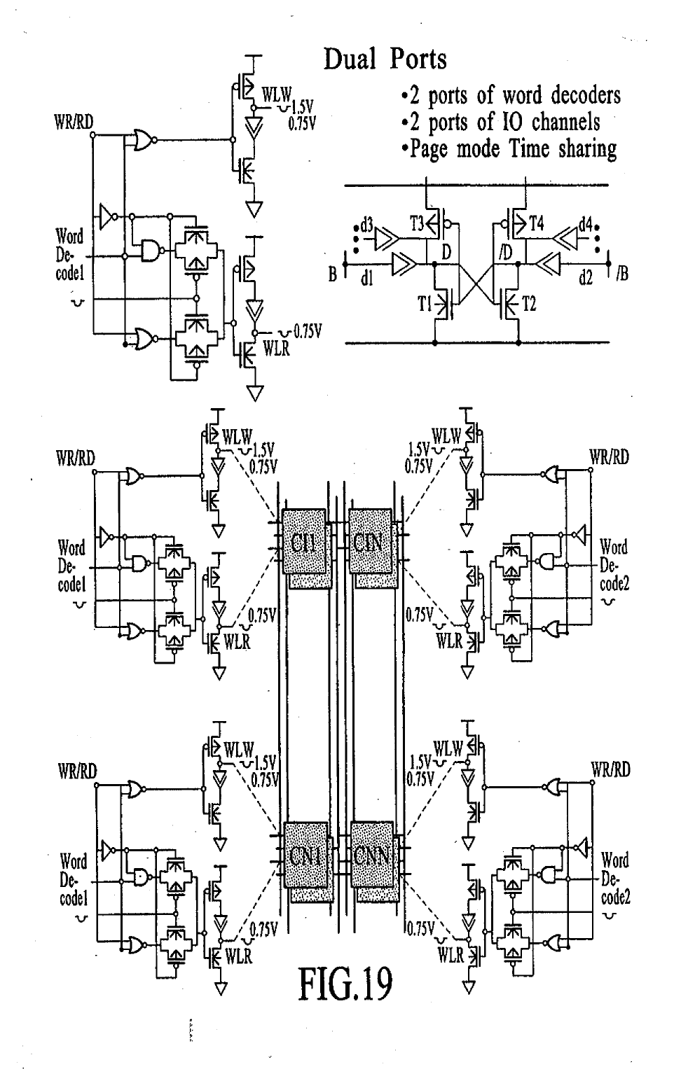

FIG. 19 discloses schemes to implement multiple (dual) port RAM arrays. Each of the array cell may attach one more pair of SBDs. Their anodes are connected to 2 sets of bit lines (B and /B). During the array write operations. Only the selected bit line pairs are activated. The idled bit lines are tri-stated. However, during the read operation each bit line pairs are independently activated and hooked up to their own sense amplifier set or time muxed to share the common sense amplifier set at the designer's discretion.

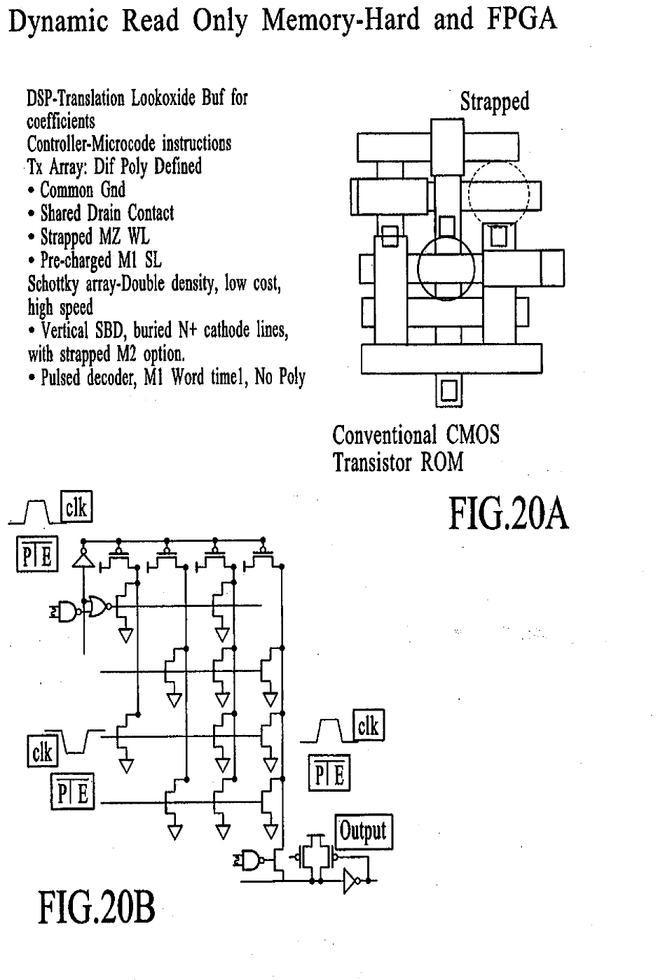

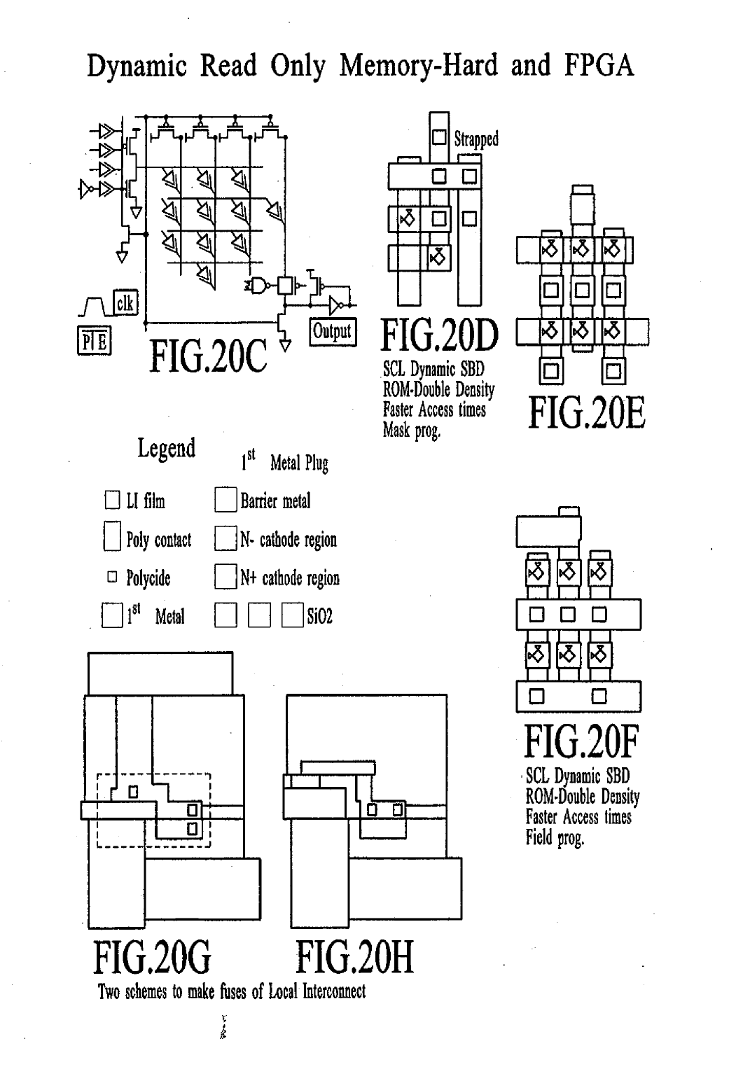

FIG. 20 discloses several schemes to implement Mask or OTP ROM or PLA. In Prior art FIG. 20A, the array is implemented by the 3-terminal CMOS transistors (for simplicity, we don't count common substrate contact). The SBD array in FIG. 20B can be implemented, wherein each bit is represented by the selected or unselected 2 terminal diode.

FIG. 20C shows a circuit diagram for SCL dynamic SBD ROM-double density faster access times (mask program and field program). 2.times. density and speed improvement is expected for the SBD version due to device size reduction, and the low power nature of the peripheral circuitry. Mask ROM (FIGS. 20D-F) is two times denser than the one time programmable. Also shown are two schemes to perform local interconnect in FIGS. 20G and 20H. The OTP is supported by prior arts either fuse blow out or anti-fuse (˜5 MA current surges) break-in with the local interconnect films.

The Other Circuit Embodiments and Applications

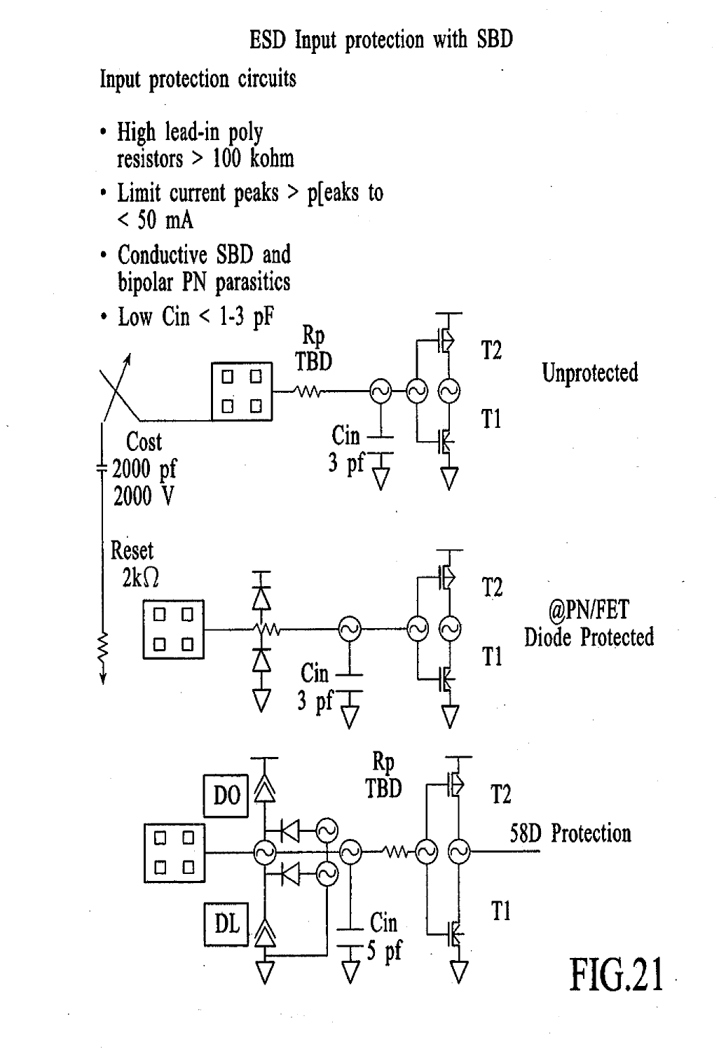

Examples of circuit blocks using SBD and CFET FETS other than SRAM cells and logic gates are shown in FIGS. 21, 22, 23A-D. Circuit blocks using SBD and CFET FETS are utilized to form signal level shifter, ESD protector, P-well, N-well PNPN latch-up suppression, localized VT controller etc. Specifically, circuit blocks using SBD and CFET FETS are used in the following ways, as shown in the figures referred to below

FIG. 21 illustrates such circuits used as an ESD protection device in the input circuitry.

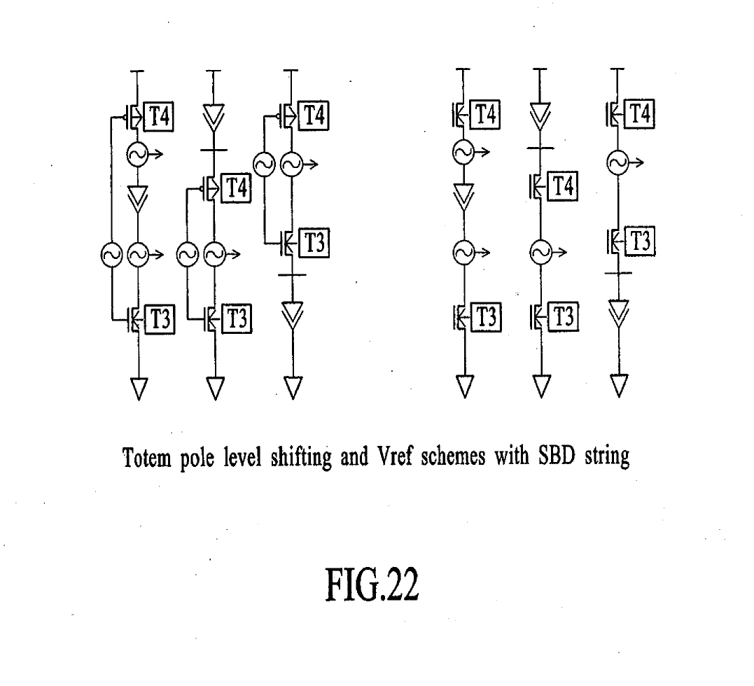

2. FIG. 22 illustrates such circuits used as level shifters and for the voltage reference circuits.

3. FIG. 22 illustrates such circuits used as level shifters with N-FET or P-FET totem pole driver for word line driver.

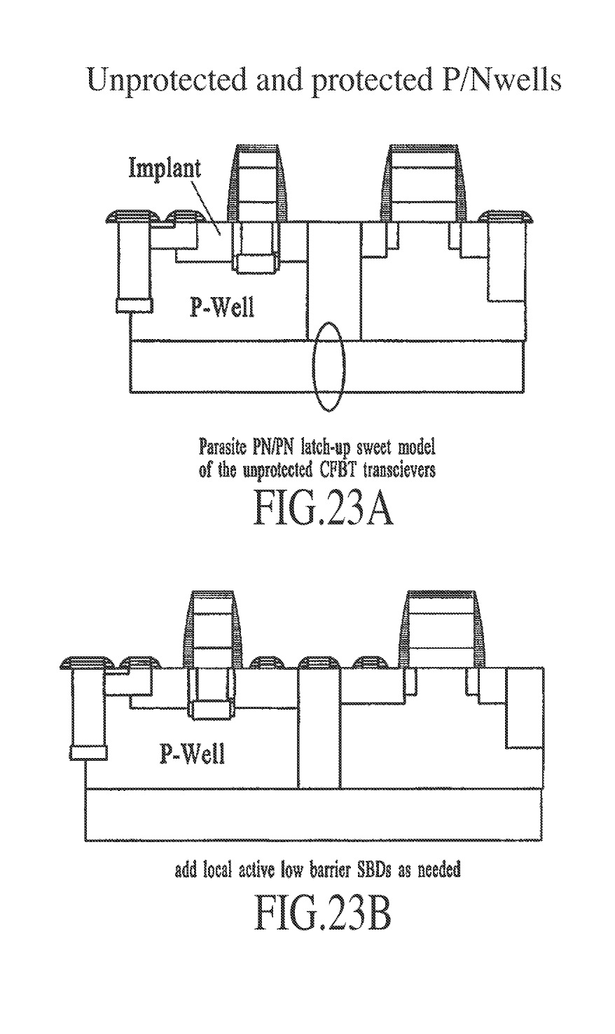

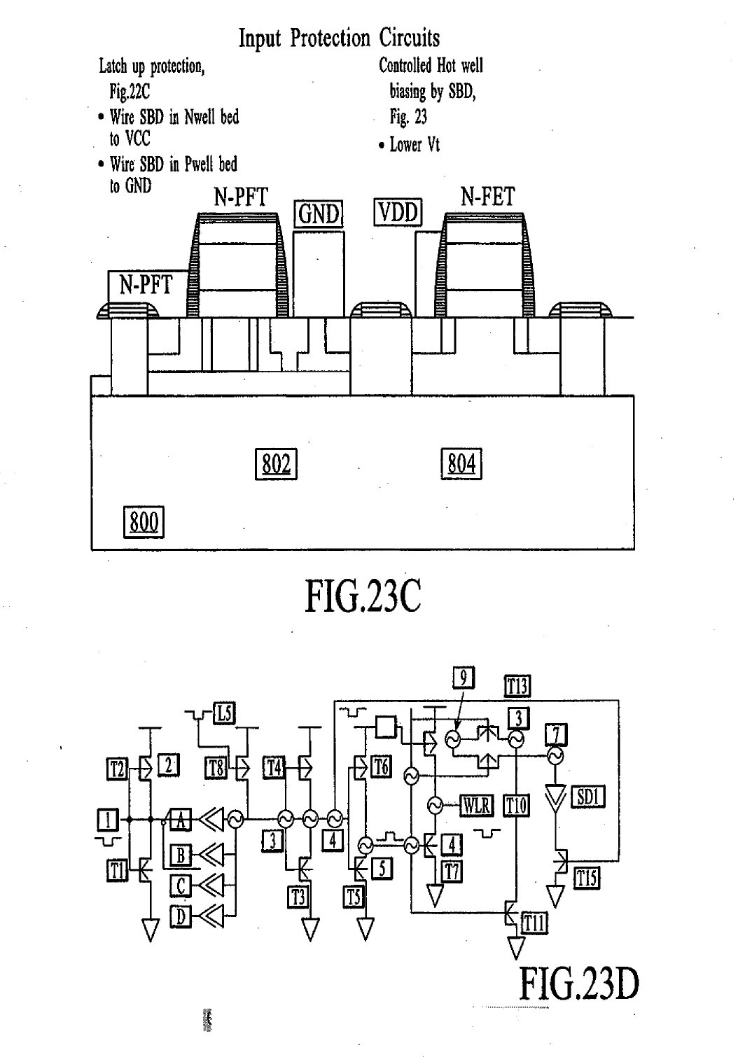

4. FIGS. 23A-23C illustrate such circuits used as clamp diodes of the parasitic NPN in the p-well region, to add SBD besides the PFET source/drain suppressing PNPN, PNP latch-up action to eliminate the conventional double guard ring structures.

5. FIG. 23D illustrates such circuits used in the P-well/N-well to affect well biasing, It may be used to harden sub-threshold leakages or to lower the VT of NFET or PFET dynamically, by circuit means, in certain regions therefore to affect threshold voltages and circuit/device parameters on the fly for a given transistor.

6. Such circuits are also utilized in ESD protection schemes.

Another application of the present invention (SCFET) is to use SBD in the input circuitry for ESD protection. FIG. 21 shows an ESD scheme, whereby SBDs are used to discharge excess charges stored externally without damaging the input gates and without speed degradation. The excitation model is a 2000 pf+/−2000 V with series resistance 2000.OMEGA.; a typical human body contact environment.

Unprotected inputs will result in a huge current spike of 1 A and a time constant of 4 uSec. This arc will strike the IC and destroy wiring and any device connected to the input pads. Conventional protection uses PN junction diodes of FET diode configurations for series resistance and current surges. However, the side effect is that such conventional protection comes with heavy speed penalty. The parasitic capacitances and series impedance easily added the Cin to several pf, the slew rate at the input gates degrades severely when receiving signals.

In the present invention, it is suggested to use SBD for the ESD protection. In FIG. 4 diode curves, it can be seen that the VF of a 0.5.times.0.5 um ideal SBD is very effective in controlling/to handle huge currents. The series cathode resistance can be very high, for it was made by a shallow N-layer near the surface. If the parasitic junction is grounded, the combined SBD of DU and DL should be adequate for ESD protection. The added input capacitance is nil, and the area is much smaller than in conventional designs.

A current path must be provided for the external body contacting with the pad and chip ground and or VCC supply while avoiding ultra high gate voltages and without increasing RC time constant in the input circuits. The present invention provides the solution by utilizing SBD and high lead-in poly resistance for current surges. Given the attribute that SBD is more conductive than FET or bipolar transistors, and also that its bulk size is considerably smaller than those devices, the circuit in accordance with the present invention will yield less parasitic input capacitance for Cin=1˜3 pf compared with 5˜10 pf with conventional solutions. Besides, the area saved may provide a benefit to the pad ring designs since the double ring protection schemes may be eliminated.

Level Shifting Schemes

While the present invention supports multilevel signals including high and low supply logic circuits, logic and Flash arrays, there are many incidents where the voltage references are drawn between the ground and VCC supplies. FIG. 22 depicts schemes where SBDs are placed in series with the totem poles or other power regulators. While the totem pole provides rail to rail references without burning DC power, series SBD chains may therefore provide other voltage references either from GND or from VCC. When PFET is on and NFET is off, Vrefs will be offset by SBD VF down from VCC. On the contrary, Vrefs will be offset by SBD VF up from GND.

Well and Latch Pp Protection Schemes

Still another advantage may be realized when the well tapping with SBDs is used to suppress the parasitic devices of the Pwell or Nwell of the CMOS transistors including the Flash arrays. FIG. 23A shows the schematic of the inherent parasitic PNP and NPN devices that are associated with the wells. One problem with this process is that array transistor operations may induce ac or dc parasitic current flows which subsequently disturb and threat the stability of the wells. Conventional practices use passive well tapping and double diffusion rings for protection. The present invention uses active SBD for efficient protection. In this respect, the low barrier SBD has considerable advantages over the high barrier SBD, since the margin against PN junction (0.7 eV) is greater.

Dynamic Vtn Control

Second, if the hot wells are charged up for the P-well, or pushed down for the N-well to the clamped diode voltage of 0.3V, it will cause the main FET devices in the localized regions VT shift toward lowering values. Therefore, this situation may be taken advantage of by biasing the wells with either cold or hot by logic switching circuits. This feature is demonstrated in concept in FIG. 23D.

In a circuit embodiment shown FIG. 23D, there is a totem pole driver pull-up device T9 with its well connected to logic circuitry which varies according state of the related signals. The circuit nodes 1-4 belong to a decoder, and therefore partial swing logic levels are needed. Node 4 has the rail-to-rail signal, and the WLR output at node 6 requires 0.75 V when idle and 0 V when selected. This is obtained by a NFET totem pole output there (T9, T7 pair). More to this point, the high level is obtained by the Vtn drop from VCC of T9. Its P-well node 9 is controlled by a biasing circuitry from nodes 7-9.

When the driver is unselected, node 9 (P-Well of T9) is biased at 0.5V via T10 and node 7, T15 and SD1 are on, T13 is off, so node 6 is at 0.8 V (T9, hot-well, Vtn=0.7V). When the driver is selected, Node 4 goes low, node 9 is biased at 0V via T13 and node 8, T10, T15 and SD1 are off, so node 6 is at 0.7 V (assume T9 Vtn=0.8V). As a result dynamic Vtn control is achieved, which gives different active device characteristics by circuit means rather than by process (Ion Implant). In a situation of making a mid-level voltage source generator without consuming dc power, this fine tweak may be an important technique.

Although the present invention has been described in accordance with the embodiments shown, one of ordinary skill in the art will readily recognize that there could be variations to the embodiments and those variations would be within the spirit and scope of the present invention. Accordingly, many modifications may be made by one of ordinary skill in the art without departing from the spirit and scope of the appended claims.

What is claimed is:

1. A mixed signal circuit comprising:
a plurality of distributed programmable I/O units;
a plurality of distributed programmable logic units;
a plurality of hardwire logic units;
a plurality of hardwired RAM files;
a plurality of hardwired multilevel storage cell (MLC) arrays; and
a programming facility for programming the distributed programmable logic units wherein software and hardware constructs are provided to the other elements of the circuits via a host system.

2. The mixed signal circuit of claim 1 wherein the software constructs configure the plurality of distributed programmable logic function.

3. The mixed signal circuit of claim 2 in which the programming facilities comprise programming voltage and current sources, clock and oscillators, state machines and counters within the distributed programmable logic unit.
